(19) United States
(12) Patent Application Publication
(10) Pub. No.: US 2015/0008513 A1
(43) Pub. Date: Jan. 8, 2015

(54) TRENCH TYPE POWER SEMICONDUCTOR DEVICE AND FABRICATION METHOD THEREOF

(71) Applicant: Anpec Electronics Corporation, Hsin-Chu (TW)

(72) Inventors: Yung-Fa Lin, Hsinchu City (TW); Chia-Hao Chang, Hsinchu City (TW)

(73) Assignee: Anpec Electronics Corporation, Hsin-Chu (TW)

(21) Appl. No.: 13/966,296

(22) Filed: Aug. 14, 2013

(30) Foreign Application Priority Data
Jul. 8, 2013 (TW) 102124379

(51) Int. Cl. H01L 29/66; H01L 29/423; H01L 21/28; H01L 29/78

(52) U.S. Cl. CPC H01L 29/66666; H01L 29/7827; H01L 29/4236; H01L 21/28008
USPC 257/330; 438/270

(57) ABSTRACT

A trench type semiconductor power device is disclosed. An epitaxial layer is formed on a semiconductor substrate. A gate trench is formed in the epitaxial layer. A gate oxide layer and a trench gate are formed in the gate trench. A spacer is provided on the gate. A metal top structure on the gate is separated from a contact structure by the spacer. The contact structure extends into the epitaxial layer. A source doping region is provided in the epitaxial layer at least between the contact structure and the gate trench.

### BACKGROUND OF THE INVENTION

1. Field of the Invention

The present invention relates generally to the field of semiconductor technology. More particularly, the present invention relates to a method for fabricating a trench type power semiconductor device.

2. Description of the Prior Art

As known in the art, the rise of on-resistance of traditional planar power DMOS devices (DMOS) is contributed from the channel region, the accumulation layer and junction field effect transistor (JFET).

In order to reduce the resistance of the above-mentioned area, trench type power devices (UMOS) are proposed. Since JFET region does not exist in a UMOS, the cell size can be reduced and the channel density is increased, thereby resulting in a lower on-resistance.

As the critical dimension of devices shrinks, the space between the gate and the contact becomes smaller and smaller, which leads to overlay alignment problems.

The present invention is concerned with a method for fabricating a trench type power semiconductor device, which is capable of solving the trench gate to contact overlay misalignment.

### SUMMARY OF THE INVENTION

According to one embodiment, a trench type power semiconductor device is disclosed. An epitaxial layer is formed on a semiconductor substrate having a first conductivity type. A gate trench is formed in the epitaxial layer. A gate oxide layer and a trench gate are formed in the gate trench. The gate protrudes from a top surface of the epitaxial layer and has recessed structure at its top portion. A spacer is provided on the gate. A metal top structure on the gate is separated from a contact structure by the spacer. The contact structure extends into the epitaxial layer. A source doping region having the first conductivity type is provided in the epitaxial layer at least between the contact structure and the gate trench.

According to one embodiment, a method for fabricating a trench type power semiconductor device is disclosed. A semiconductor substrate having a first conductivity type is provided. An epitaxial layer is formed on the semiconductor substrate. Gate trenches are formed in the epitaxial layer. A gate oxide layer is formed in the gate trenches. A gate is formed in the gate trenches. The gate protrudes from a top surface of the epitaxial layer. A source doping region is formed in the epitaxial layer. The source doping region has the first conductivity type. A spacer is formed on a sidewall of the gate. Using the spacer as an etching hard mask, the source doping region is etches in a self-aligned manner, thereby forming a contact hole. A contact structure is formed in the contact hole and a metal top structure formed on the gate. The contact structure is separated from the metal top structure by the spacer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1˜13 are schematic, cross-sectional diagrams illustrating an exemplary method for fabricating a trench type power semiconductor device in accordance with one embodiment of this invention.

FIGS. 14˜17 are schematic, cross-sectional diagrams illustrating a method for fabricating a trench type power semiconductor device in accordance with another embodiment of this invention.

FIGS. 18˜20 illustrate exemplary layouts of the contact holes and the trench gates.

### DETAILED DESCRIPTION

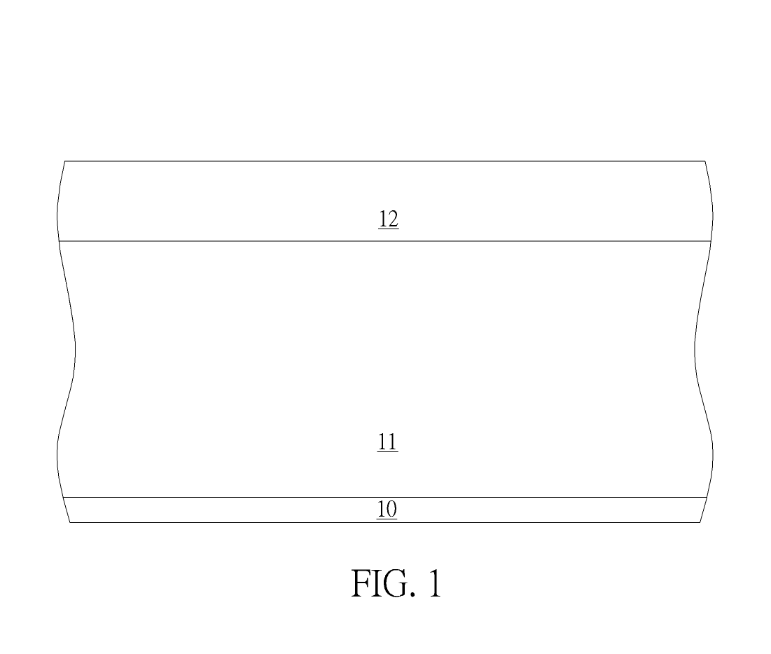

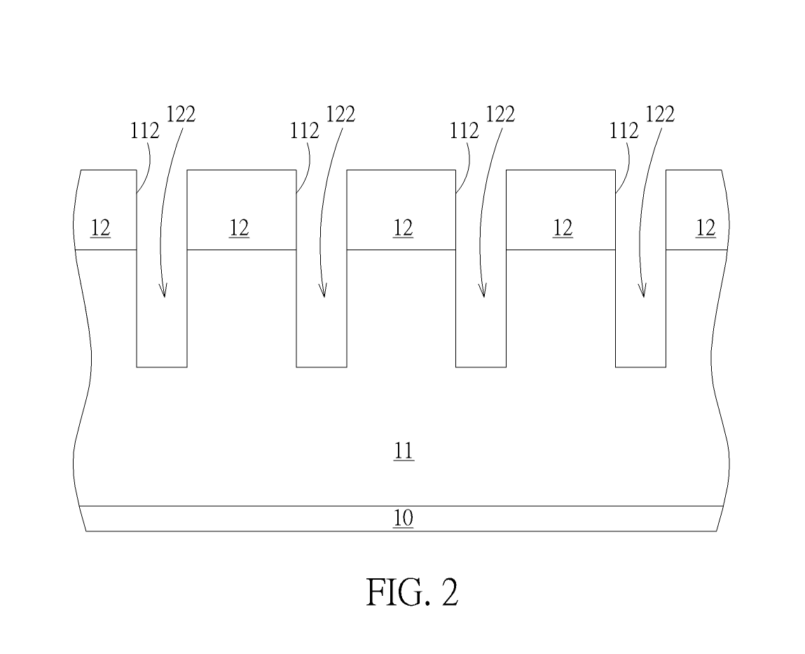

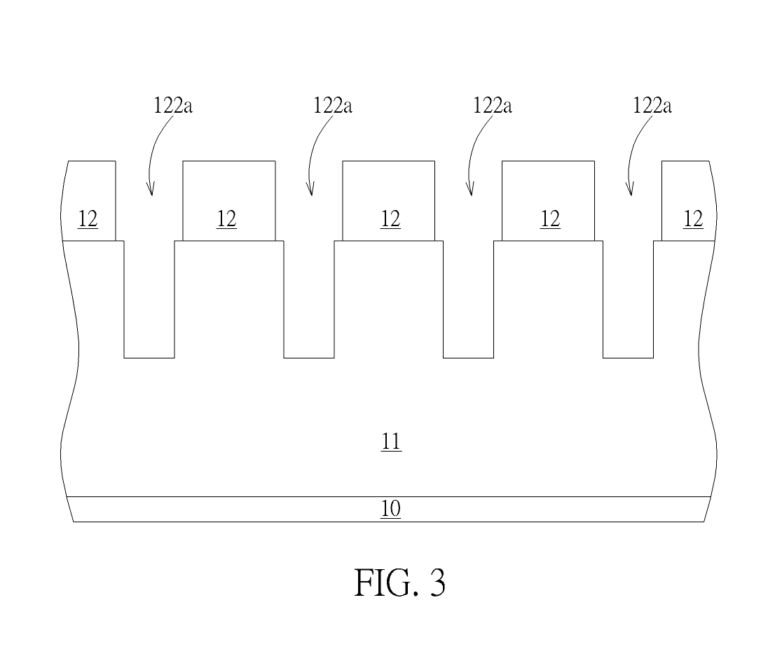

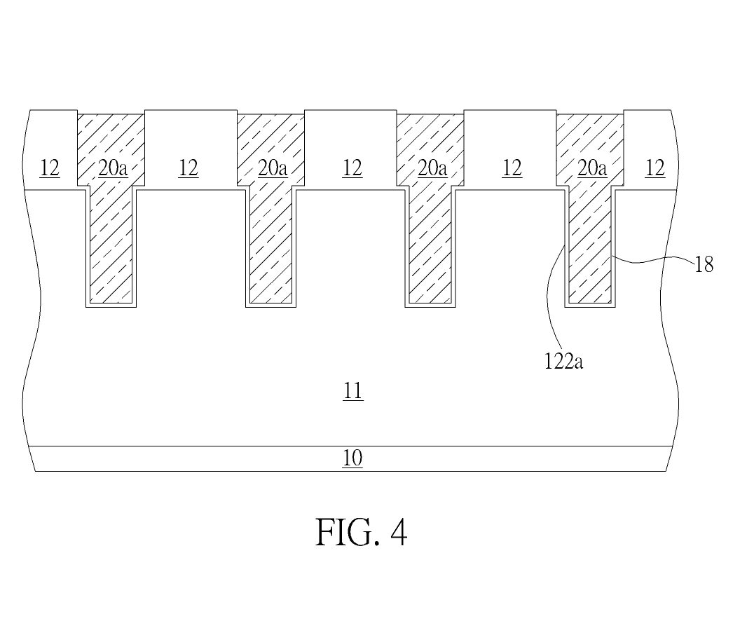

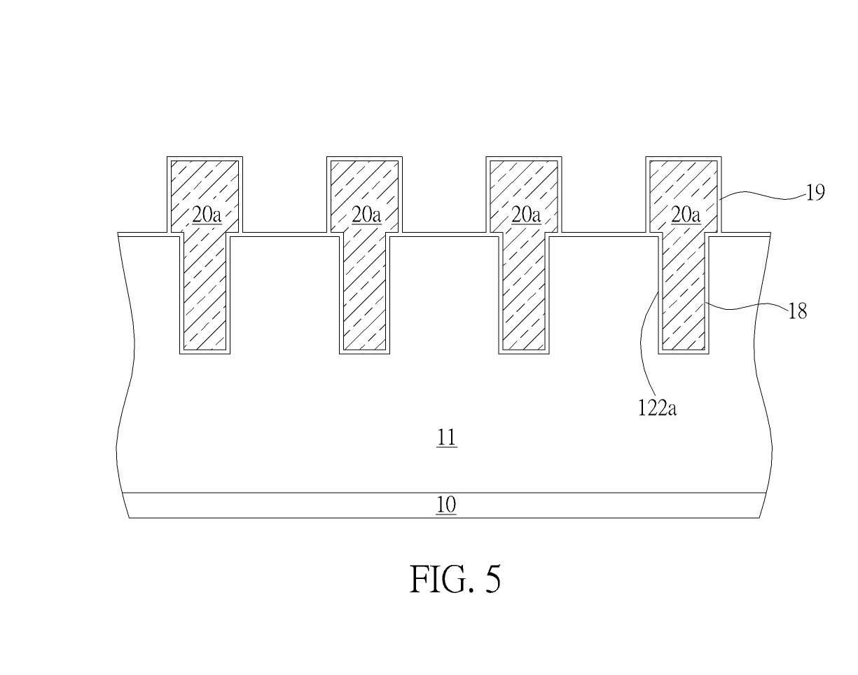

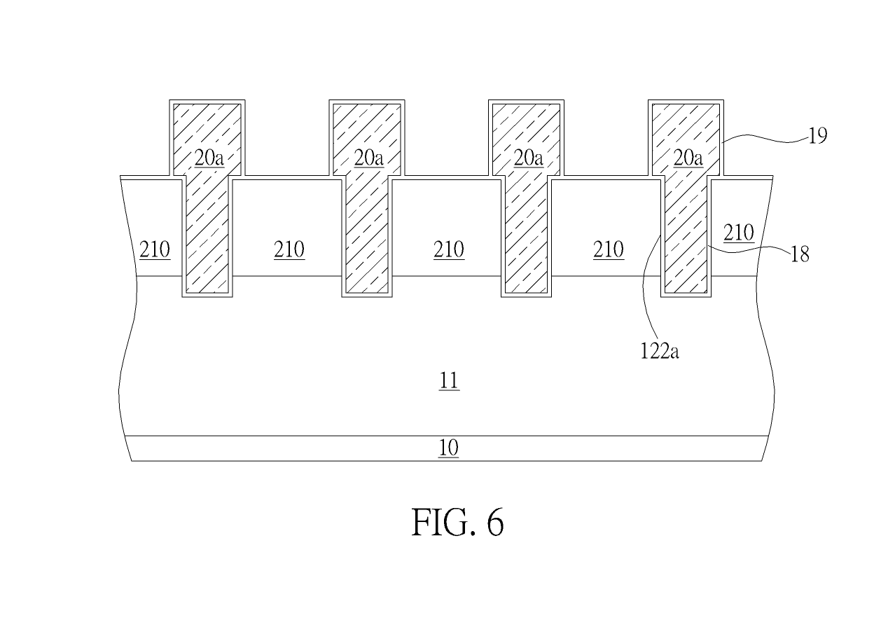

FIGS. 1˜13 are schematic, cross-sectional diagrams illustrating an exemplary method for fabricating a trench type power semiconductor device in accordance with one embodiment of this invention. As shown in FIG. 1, a semiconductor substrate 10 such as an N type heavily doped silicon substrate is provided. The semiconductor substrate 10 may function as a drain of the transistor device. An epitaxial layer 11 such as an N type epitaxial silicon layer is formed on the semiconductor substrate 10 by using an epiaxial growth process. A hard mask 12 is then formed on the epitaxial layer 11. For example, the hard mask 12 may comprise a silicon oxide layer or a silicon nitride layer.

As shown in FIG. 2, openings 112 are formed in the hard mask layer 12 by using lithographic and etching processes. The openings 112 may be defined by a photoresist layer (not shown) in a lithographic process. After removing the photoresist layer, a dry etching process is carried out to etch the epitaxial layer 11 through the openings 112 in the hard mask layer 12 to a predetermined depth, thereby forming gate trenches 122.

As shown in FIG. 3, an oxidation process may be performed to form a sacrificial oxide layer (not shown) on the surfaces of the gate trenches 122. A portion of the hard mask layer 12 and the sacrificial oxide layer are then removed, thereby forming gate trenches 122a.

As shown in FIG. 4, a thermal oxidation process is carried out to form a gate oxide layer 18 on the top surface of the epitaxial layer 11 and the interior surface of each of the gate trenches 122a. A chemical vapor deposition (CVD) process is then performed to deposit a polysilicon layer (not explicitly shown) in a blanket manner. The polysilicon layer fills into the gate trenches 122a. An etching or polishing process is then performed to remove excess polysilicon layer outside the gate trenches 122a and the remaining polysilicon layer within each of the gate trenches 122a constitutes trench gate 20a. It is understood that in addition to polysilicon, the gate trenches 122 may be composed of other materials such as metals or metal silicides.

As shown in FIG. 5, the remaining hard mask layer 12 is completely removed to reveal the top surface and an upper sidewall of each of the trench gates 20a. An oxidation process is then performed to form an oxide layer 19 on the exposed top surface and upper sidewall of each of the trench gates 20a.

As shown in FIG. 6, an ion implantation process is then performed to form doping regions in the epitaxial layer 11 between the trench gates 20a. Subsequently, a thermal drive-in process at temperatures between, for example, 900˜1200° C., may be performed to diffuse or activate the dopants in the doping regions, thereby forming ion wells 210.

As shown in FIG. 7, another ion implantation process is then performed to form source doping regions 22 in the epitaxial layer 11 adjacent to the gate trenches 122. The source doping regions 22 may be N+ source doping regions. Subsequently, a thermal drive-in process may be performed to diffuse or activate the dopants. It is understood that a lithographic process may be carried out to define the source regions to be implanted by using a photoresist pattern prior to the ion implantation process.

As shown in FIG. 8, a spacer material layer (not explicitly shown), for example, silicon nitride, is deposited over the semiconductor substrate 10 in a blanket manner. The spacer material layer has a thickness less than 0.2 micrometers. An anisotropic dry etching process is performed to form spacers 24 on the upper sidewalls of the trench gates 20a. The confronted spacers 24 between two adjacent trench gates 20a define an opening 24a on the source doping region 22. The opening 24a exposes a portion of the source doping region 22. The dimension of the opening 24a may be determined by the thickness at the foot of each of the spacers 24.

As shown in FIG. 9, through the openings 24a between the spacers 24, the epitaxial layer 11 is etched to a predetermined depth thereby forming the contact holes 230 in a self-aligned manner. Since the contact holes 230 are formed in a self-aligned manner, the misalignment of the lithographic process is avoided. The depth of the contact holes 230 may be equal to or deeper than the junction depth of the source doping region 22. When etching the contact holes 230, the trench gates 20a are concurrently etched, thereby forming a recessed structure 20b at the top portion of each of the trench gates 20a.

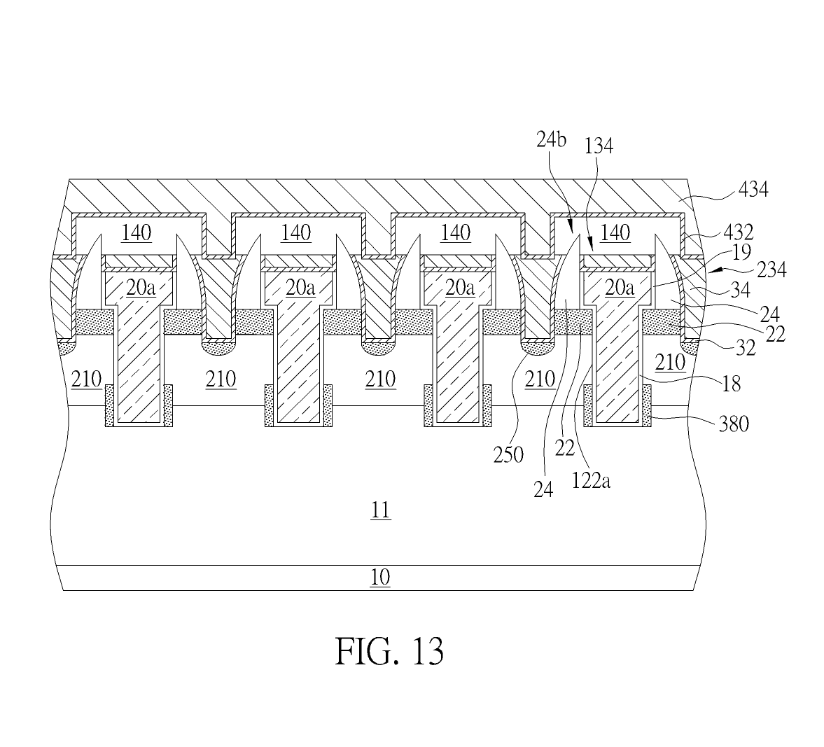

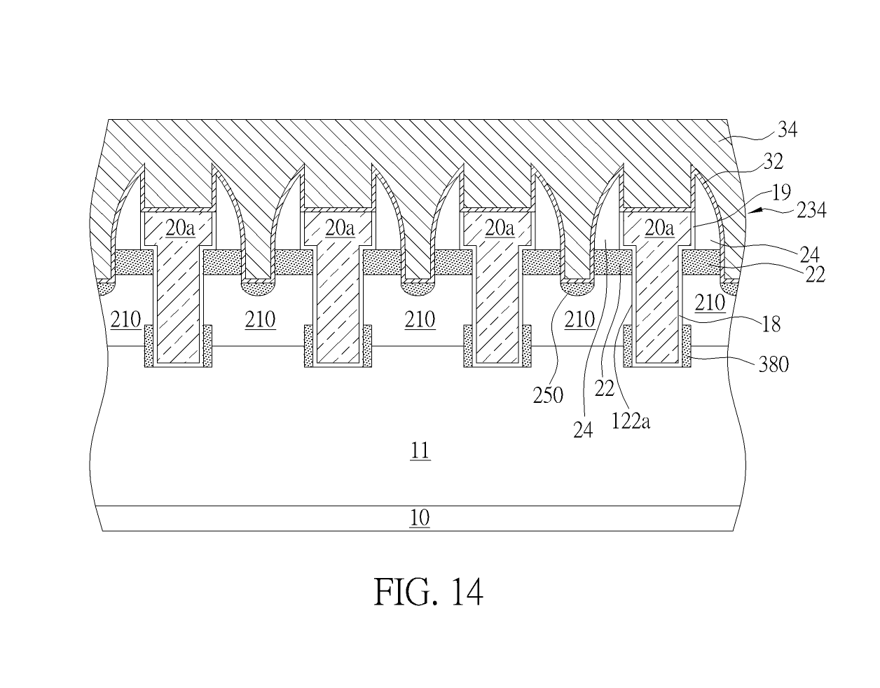

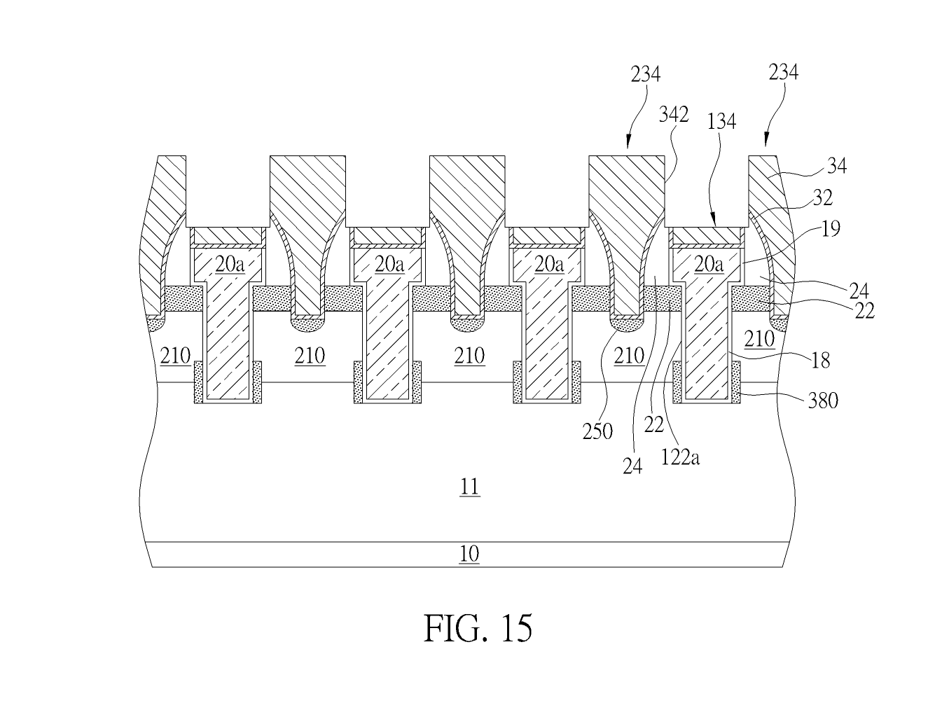

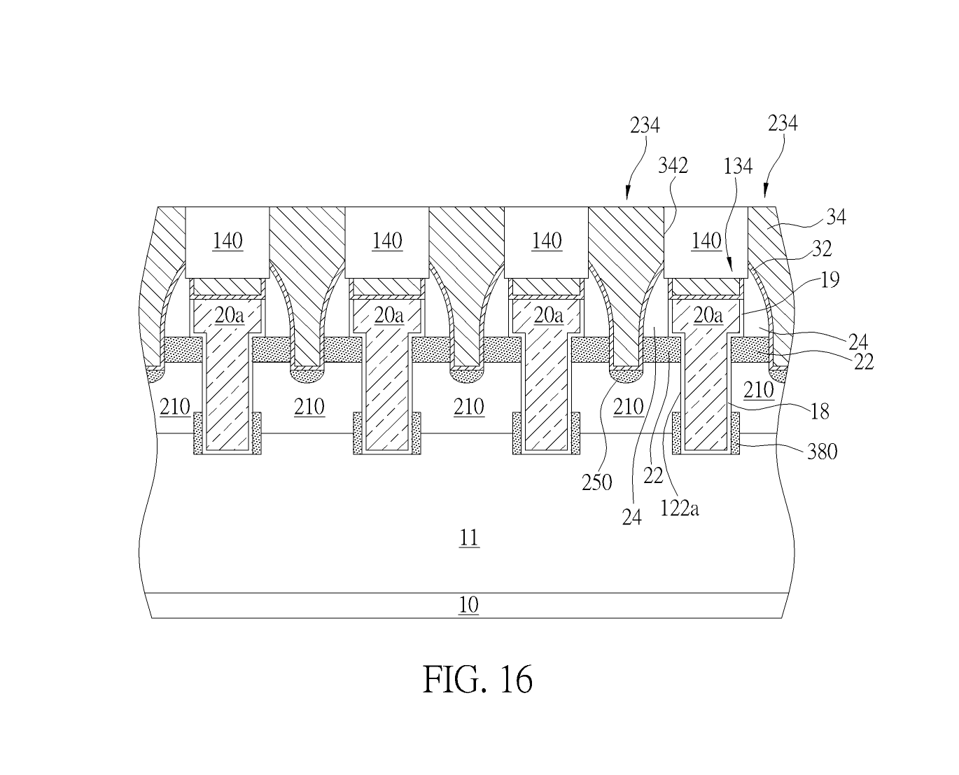

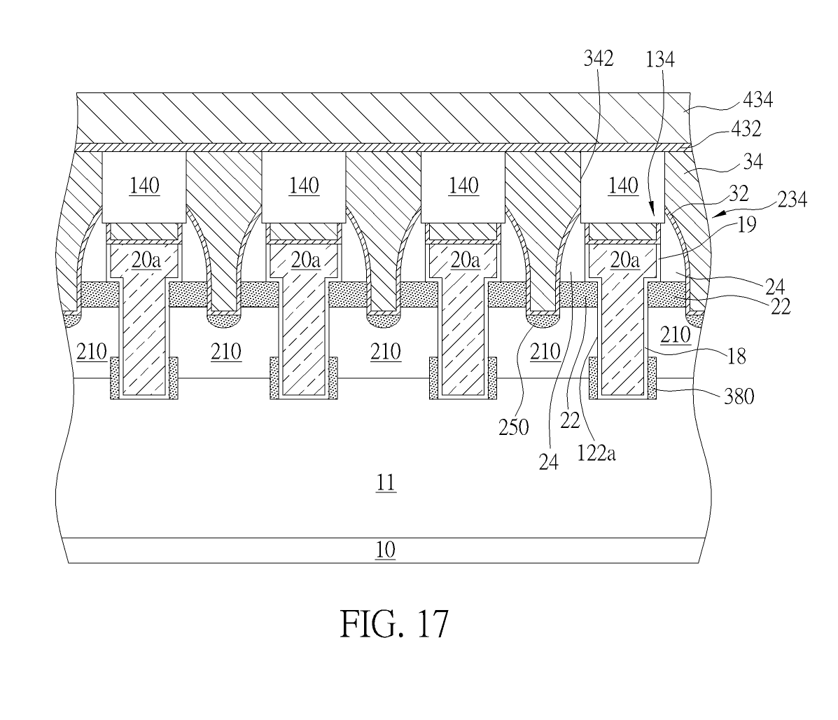

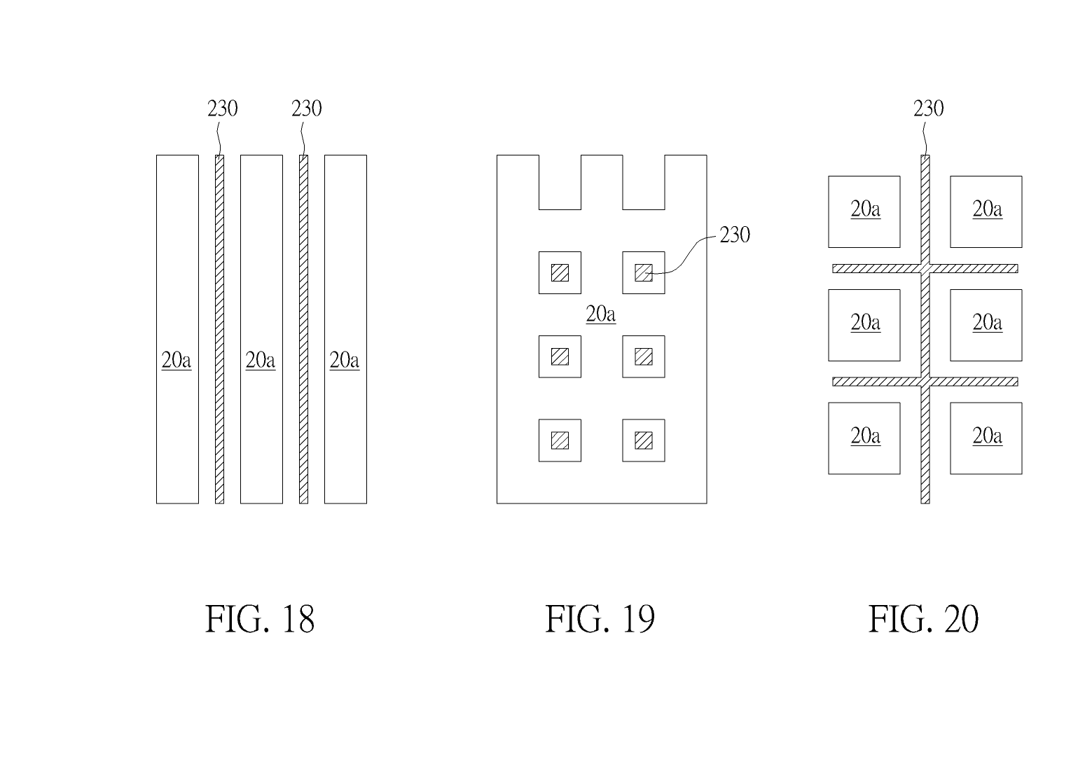

The exemplary layouts of the contact holes 230 and the trench gates 20a are shown in FIGS. 18˜20. As shown in FIG. 18, the straight line shaped contact hole pattern is in parallel with the straight line shaped trench gate pattern. In FIG. 19, the trench gate pattern surrounds the contact hole pattern. In FIG. 20, the grid shaped contact hole pattern separates the trench gate pattern. The above-described layouts are for illustration purposes. The invention should not be limited thereto.

As shown in FIG. 10, a tilt-angle ion-implantation process is then performed to implant P type dopants into the epitaxial layer 11 adjacent to the gate trenches 122a, thereby forming sidewall doping regions 380. A contact hole ion-implantation process is then performed to form contact doping region 250 such as P+ doping region at the bottom of each of the contact holes 230. Subsequently, a rapid thermal annealing process may be performed.

As shown in FIG. 11, a barrier layer 32 and a metal layer 34 are deposited in a blanket manner. The contact holes 230 may be filled with the metal layer 34. The barrier layer 32 may comprise titanium or titanium nitride. The metal layer 34 may comprise tungsten. A polishing or etching process may be performed to remove an upper portion of the metal layer 34 and barrier layer 32 to expose a protruding tip portion 24b of each of the spacers 24 that separates a metal top structure 134 within the recessed structure 20b from the contact structure 234 within the contact hole 230. The metal top structure 134 comprises the barrier layer 32 and the metal layer 34. As can be seen in FIG. 11, the tip portion 24b protrudes from the top surface of the metal layer 34. The metal top structure 134 helps reduce the electrical resistance of the trench gate 20a.

As shown in FIG. 12, a CVD process is performed to deposit a dielectric layer 140 in a blanket manner. The dielectric layer 140 covers the metal layer 34 and the tip portion 24b. A lithographic process is then performed to form a photoresist pattern (not shown) on the dielectric layer 140 to define the position and pattern of via holes. Then, using the photoresist pattern as an etching hard mask, the dielectric layer 140 is etched to a predetermined depth till a portion of the contact structure 234 is exposed thereby forming the via hole 240. The photoresist pattern is then removed.

As shown in FIG. 13, a barrier layer 432 and a metal layer 434 are deposited in a blanket manner. The metal layer 434 fills the via hole 240 to thereby form interconnection.

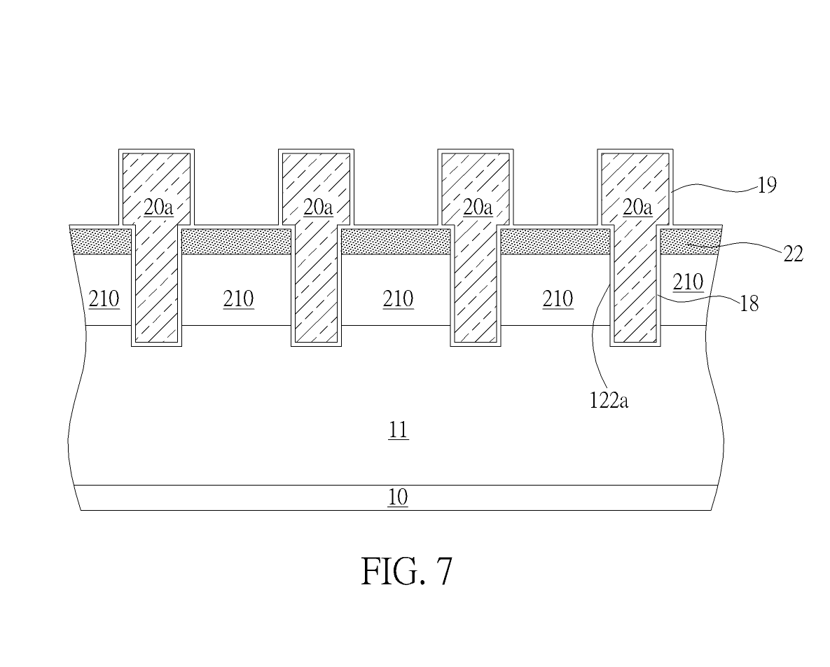

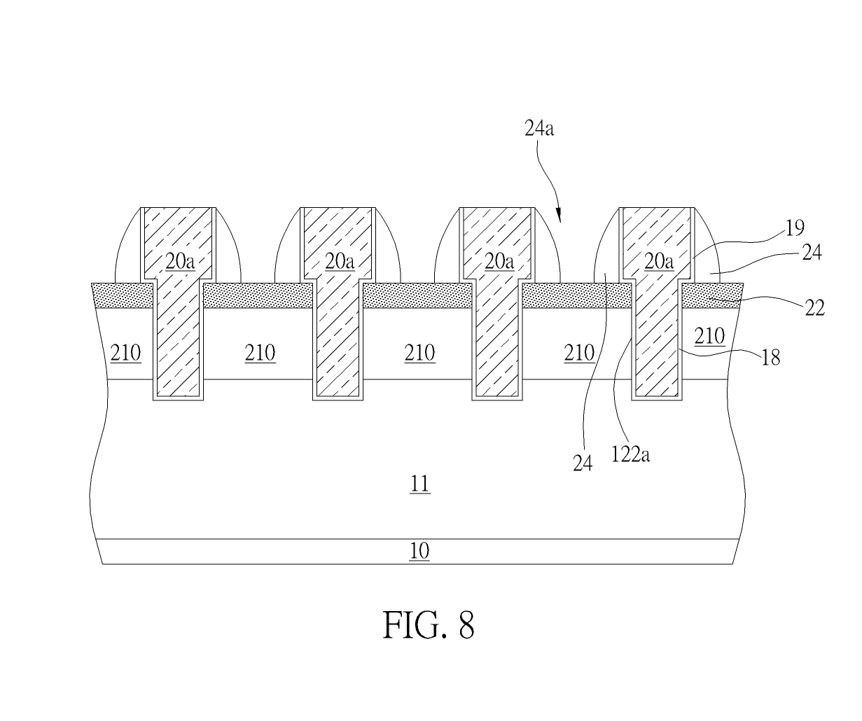

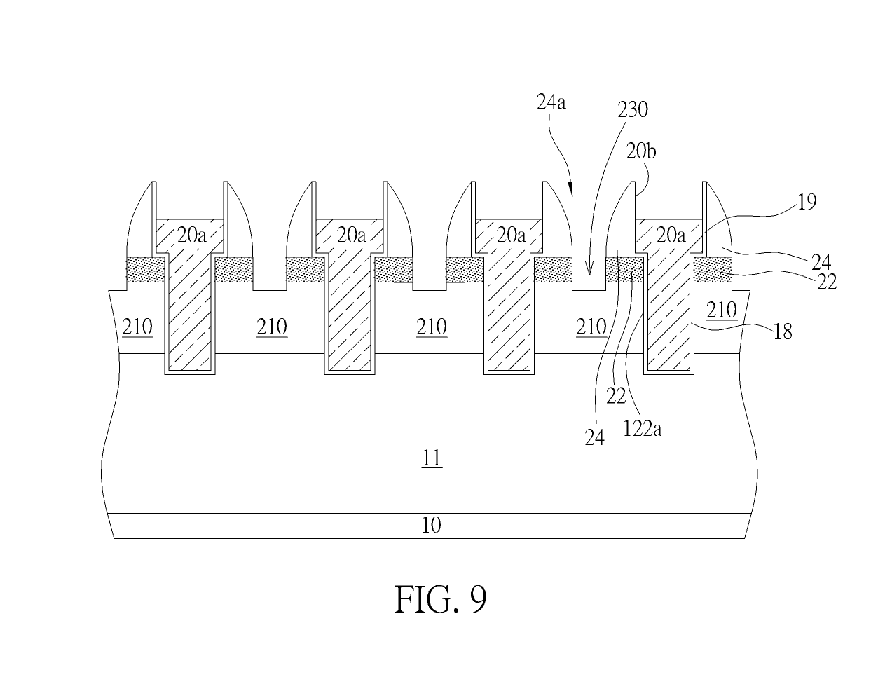

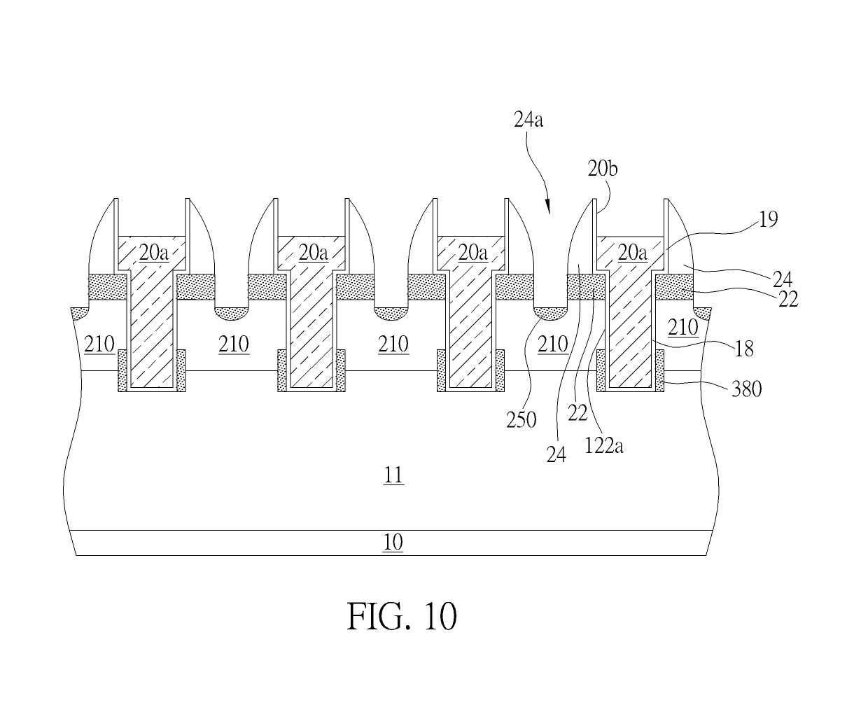

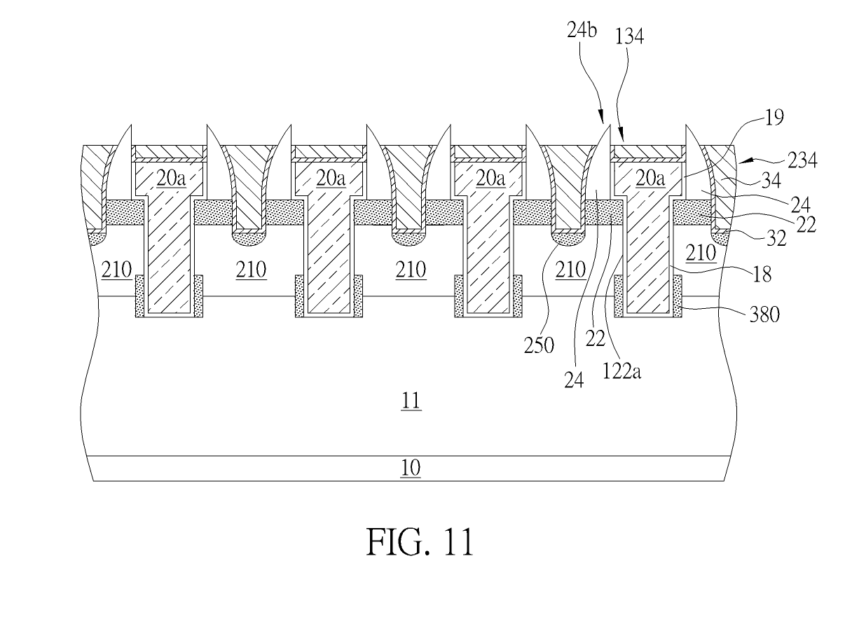

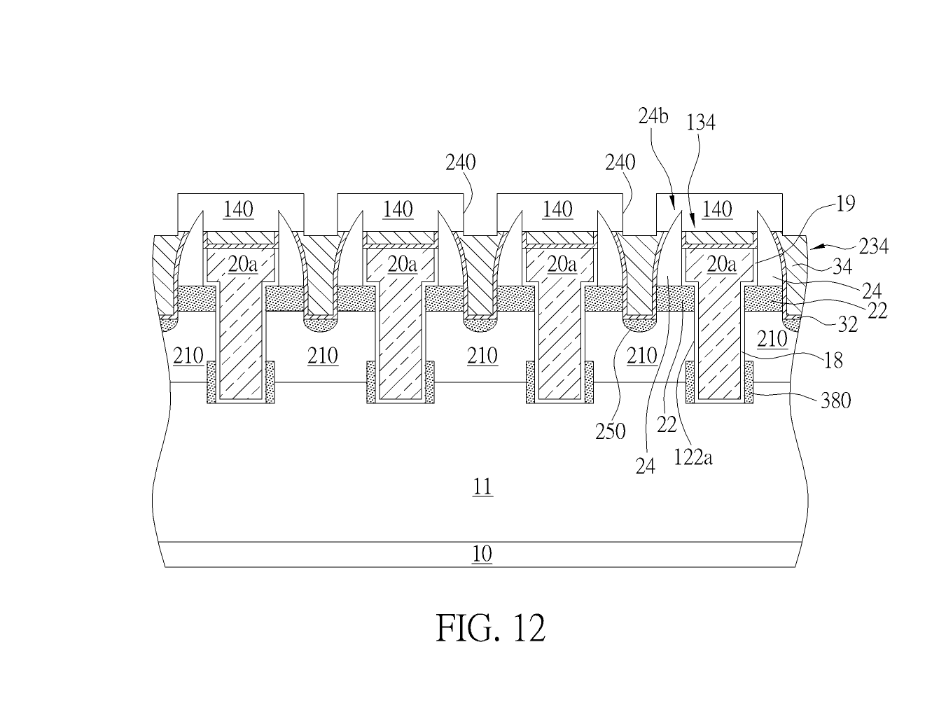

FIGS. 14˜17 are schematic, cross-sectional diagrams illustrating a method for fabricating a trench type power semiconductor device in accordance with another embodiment of this invention, wherein FIG. 14 follows the steps set forth in FIG. 10 and the previous steps are omitted. As shown in FIG. 14, the barrier layer 32 and the metal layer 34 are deposited to fill the contact holes 230 and the recessed structure 20b at the top portion of the trench gate 20a.

As shown in FIG. 15, lithographic and etching processes are performed to etch away a portion of the barrier layer 32 and the metal layer 34 directly above the trench gate 20a. A portion of the spacer 24 is also etched away to thereby separate the metal top structure 134 from the contact structure 234. At this point, a recess 342 is formed in the metal layer 34 directly above the trench gate 20a.

As shown in FIG. 16, a dielectric layer 140 is deposited to cover the metal layer 34. The dielectric layer 140 also fills into the recess 342. A polishing process such as a chemical mechanical polishing (CMP) process is carried out to remove the dielectric layer 140 from the top surface of the contact structure 234, while leaving the dielectric layer 140 in the recess 342 intact, thereby forming a planar surface.

As shown in FIG. 17, a barrier layer 432 and a metal layer 434 are deposited in a blanket manner to thereby form interconnection with the contact structure 234.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A trench type power semiconductor device, comprising:
a semiconductor substrate having a first conductivity type;
an epitaxial layer on the semiconductor substrate;
at least one gate trench extending into the epitaxial layer;
a gate oxide layer in the gate trench;
a gate in the gate trench, wherein the gate protrudes from a top surface of the epitaxial layer and has recessed structure at its top portion;
a spacer on a sidewall the gate;
a metal top structure within the recessed structure;
a contact structure on one side of the spacer and extending into the epitaxial layer, wherein the spacer separates the metal top structure from the contact structure; and
a source doping region in the epitaxial layer between the contact structure and the gate trench, wherein the source doping region has the first conductivity type.

2. The trench type power semiconductor device according to claim 1 wherein the semiconductor substrate acts as a drain of the trench type power semiconductor device.

3. The trench type power semiconductor device according to claim 1 further comprising an ion well between the contact structure and the gate trench, wherein the ion well has a second conductivity type.

4. The trench type power semiconductor device according to claim 3 wherein the first conductivity type is N type and the second conductivity type is P type.

5. The trench type power semiconductor device according to claim 1 wherein the spacer protrudes from a top surface of the metal top structure to constitute a tip portion.

6. The trench type power semiconductor device according to claim 1 further comprising:
a dielectric layer covering the metal top structure and the spacer; and
at least a metal layer covering the dielectric layer and electrically connecting the contact structure.

7. A method for fabricating a trench type power semiconductor device, comprising:
providing a semiconductor substrate having a first conductivity type;
forming an epitaxial layer on the semiconductor substrate;
forming gate trenches in the epitaxial layer;
forming a gate oxide layer in each said gate trench;
forming a gate in each said gate trench, wherein the gate protrudes from a top surface of the epitaxial layer;
form a source doping region in the epitaxial layer, wherein the source doping region has the first conductivity type;
forming a spacer on a sidewall of the gate;
using the spacer as an etching hard mask to self-aligned etching the source doping region thereby forming a contact hole; and
forming a contact structure in the contact hole and a metal top structure on the gate, wherein the contact structure is separated from the metal top structure by the spacer.

8. The method for fabricating a trench type power semiconductor device according to claim 7 further comprising the following steps after forming the contact structure:
depositing a dielectric layer in a blanket manner to cover the contact structure and the metal top structure;
etching the dielectric layer to form a via hole exposing a portion of the contact structure; and
depositing a metal layer in a blanket manner to electrically connect the contact structure through the via hole.

9. The method for fabricating a trench type power semiconductor device according to claim 7 further comprising to following steps before forming the source doping region:
forming an ion well having a second conductivity type between the gate trenches in the epitaxial layer.

10. The method for fabricating a trench type power semiconductor device according to claim 9 wherein the first conductivity type is N type and the second conductivity type is P type.

11. The method for fabricating a trench type power semiconductor device according to claim 7 wherein the semiconductor substrate acts as a drain of the trench type power semiconductor device.
